(19) United States
(12) Patent Application Publication
(10) Pub. No.: US 2007/0257361 A1
(43) Pub. Date: Nov. 8, 2007

(54) CHIP PACKAGE

(75) Inventor: Chi-Hsing Hsu, Taipei Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: VIA TECHNOLOGIES, INC., Taipei Hsien (TW)

(21) Appl. No.: 11/564,846

(22) Filed: Nov. 30, 2006

(30) Foreign Application Priority Data
May 3, 2006 (TW) 95115699

(51) Int. Cl. H01L 23/48; H01L 23/52; H01L 29/40

(52) U.S. Cl. 257/734

(57) ABSTRACT

A chip package includes a first wiring layer, chips, a second wiring layer, dielectric layers, first conductive vias, and second conductive vias. The first wiring layer has contacts near a side of the first wiring layer. The chips are stacked over the first wiring layer. The second wiring layer is stacked over the first wiring layer. The dielectric layers are disposed between the first wiring layer, the chips, and the second wiring layer. The first conductive vias are inside at least one of the dielectric layer for electrically connecting the chip to the second wiring layer. The second conductive vias are inside at least one of the dielectric layers for electrically connecting the second wiring layer to the first wiring layer.

### CROSS-REFERENCE TO RELATED APPLICATION

This application claims the priority benefit of Taiwan application serial no. 95115699, filed May 3, 2006. All disclosure of the Taiwan application is incorporated herein by reference.

### BACKGROUND OF THE INVENTION

1. Field of Invention

The present invention relates to a chip package. More particularly, the present invention relates to a thinned chip package, and to a chip package of multi-chip module.

2. Description of Related Art

In current information society, customers demand for high speed, high quality, and multi-function electronic products. In the aspect of appearance, the design of electronic products tends to be light, thin, short, and small.

In order to meet the above demand, many companies adopt the concept of systematization in circuit design, such that a single chip may has multiple functions, and the number of the chips disposed in the electronic products can be reduced.

Further, for the electronic packaging technology, in order to accord with the design trend of light, thin, short, and small products, packaging design concepts such as multi-chip module (MCM) and chip scale package (CSP) have been developed.

A stacked package structure with the packaging design concept of MCM is illustrated in the following.

FIG. 1 is a schematic cross-sectional view of the conventional stacked chip package structure.

Referring to FIG. 1, the conventional stacked chip package structure 100 is a secure digital card (SD card), which comprises a wiring substrate 110, a memory chip 120, another memory chip 130, and a dielectric layer 140.

The wiring substrate 110 has a dielectric layer 112 and a wiring layer 114. The dielectric layer 112 has an opening 112a, wherein the opening 112a is near a side of the dielectric layer 112. The wiring layer 114 has a plurality of contacts 114a. The wiring layer 114 is disposed on the dielectric layer 112, and the opening 112a exposes a part of the contacts 114a.

The memory chip 120 is disposed on the wiring layer 114 and is electrically connected to the wiring layer 114 through bonding wires 150.

The memory chip 130 is stacked on the memory chip 120 and is electrically connected to the memory chip 120 through bonding wires 152.

The dielectric layer 140 is disposed on the wiring layer 114, the memory chip 120, and the memory chip 130, and the memory chip 120, the memory chip 130, the bonding wires 150, and the bonding wires 152 are covered by the dielectric layer 140.

Because the memory chip 120 and the memory chip 130 can be electrically connected to the wiring layer 114 through the bonding wires 150 and the bonding wires 152, a user can access digital data of the memory chip 120 and the memory chip 130 through the contacts 114a.

It should be noted that in the stacked chip package structure 100, since the dielectric layer 140 must cover all the memory chip 120, the memory chip 130, the bonding wires 150, and the bonding wires 152, and since a minimum wiring height of the bonding wires 152 must be maintained, it is difficult to further reduce the thickness of the stacked chip package structure 100 according to the conventional art.

Further, the conventional art can directly stack the smaller memory chip 130 on the bigger memory chip 120 as shown by the stacked chip package structure 100, and can also stack a plurality of chips with approximate size on a wiring substrate through a plurality of spacers and electrically connect the chips to the wiring substrate through a plurality of bonding wires, wherein the spacers are respectively disposed between two adjacent chips for separating the adjacent chips. However, since the spacers also have a certain thickness, the use of the spacers makes it more difficult to reduce the thickness of the stacked chip package structure.

### SUMMARY OF THE INVENTION

The present invention provides a chip package, which comprises a first wiring layer, chips, second wiring layers, dielectric layers, first conductive through holes, and second conductive through holes. The first wiring layer has contacts near a side of the first wiring layer. The chips are stacked over the first wiring layer. The second wiring layer is stacked over the first wiring layer. The dielectric layers are disposed between the first wiring layer, the chips, and the second wiring layers. The first conductive through hole is inside the dielectric layer for electrically connecting the chip to the second wiring layer. The second conductive through hole is inside the dielectric layer for electrically connecting the second wiring layer to the first wiring layer.

The present invention provides a chip package, which comprises a dielectric layer having a first side surface and a second side surface, a first chip disposed in the dielectric layer, a second chip disposed in the dielectric layer, a first wiring layer disposed on the first side surface, and a second wiring layer disposed on the second side surface. The first chip and the second chip are respectively connected to the first wiring layer and the second wiring layer, and the first wiring layer is electrically connected to the second wiring layer.

In order to the make aforementioned features and advantages of the present invention comprehensible, preferred embodiments accompanied with figures are described in detail below.

### BRIEF DESCRIPTION OF THE DRAWINGS

FIG. 1 is a schematic cross-sectional view of the conventional stacked chip package structure.

FIG. 2 is a schematic cross-sectional view of the chip package of an embodiment of the present invention.

FIG. 3 is a schematic cross-sectional view of the chip package of another embodiment of the present invention.

FIG. 4 is a schematic cross-sectional view of the chip package of still another embodiment of the present invention.

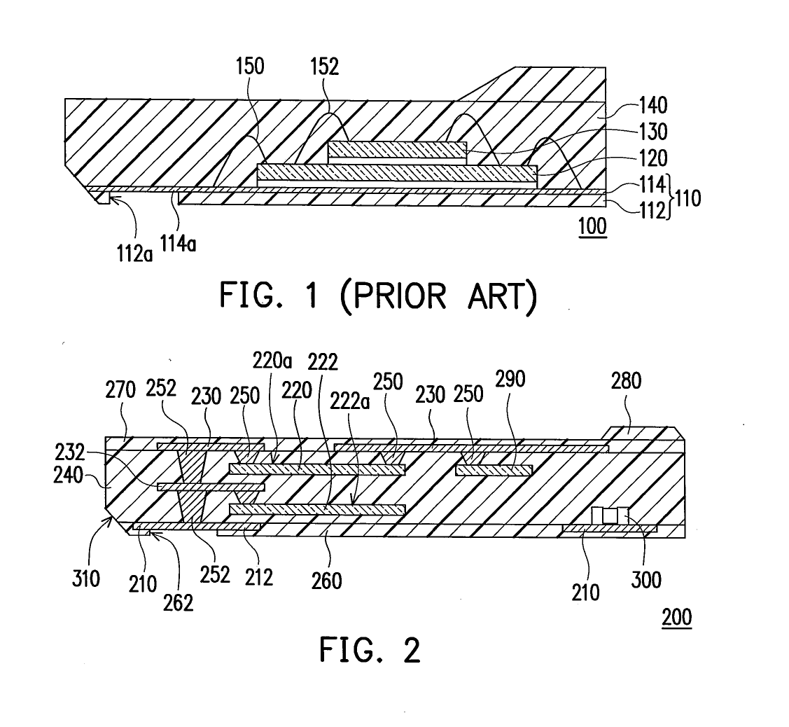

### DESCRIPTION OF EMBODIMENTS

In the present invention, a chip package is referred to as a component formed by wrapping at least one chip through a packaging process. In other words, the chip package is an electronic component having at least one chip.

FIG. 2 is a schematic cross-sectional view of the chip package of an embodiment of the present invention.

Referring to FIG. 2, the chip package 200 mainly comprises a wiring layer 210, a chip 220, a chip 222, a wiring layer 230, a wiring layer 232, a multi-layer dielectric layer 240, a plurality of conductive through holes 250, and a plurality of conductive through holes 252.

The wiring layer 210 has a plurality of contacts 212, wherein the contacts 212 are near a side of the wiring layer 210.

The chip 220 has an active surface 220a, and the chip 222 has an active surface 222a. The chip 220 and the chip 222 are respectively stacked over the wiring layer 210, and the chip 222 is disposed between the chip 220 and the wiring layer 210. The active surface 220a and the active surface 222a face in the same direction.

In the present embodiment, the chip 220 and the chip 222 may be the same chip, for example, both of the chip 220 and the chip 222 are a driver IC chip. However, the chip 220 and the chip 222 may be different chips, for example, the chip 220 is a driver IC chip and the chip 222 is a control IC chip.

In the present embodiment, the active surface may be a chip surface having one or more pads that are used to be electrically connected to an external component (not shown). In addition, the active surface may be a chip surface having one or more electrical connection terminals that are used to be electrically connected to the external component (not shown).

Referring to FIG. 2, the wiring layer 230 and the wiring layer 232 are stacked over the wiring layer 210. More particularly, the wiring layer 230 is disposed over the chip 220, and the wiring layer 232 is disposed between the chip 220 and the chip 222. The multi-layer dielectric layer 240 has many dielectric layers that are respectively disposed between any adjacent two of the wiring layer 210, chip 220, chip 222, wiring layer 230, and wiring layer 232.

In the present embodiment, the wiring layer 230 and the corresponding wiring layer 232 may have the same circuit. In another embodiment of the present invention, the circuits of the wiring layer 230 and the corresponding wiring layer 232 may be different circuits.

Referring to FIG. 2, the conductive vias 250 are disposed in the dielectric layer 240, wherein one part of the conductive vias 250 electrically connect the chip 220 to the wiring layer 230, and another part of the conductive vias 250 electrically connect the chip 222 to the wiring layer 232.

Further, the conductive vias 252 are disposed in the dielectric layer 240 for electrically connecting the wiring layer 230 and the wiring layer 232 to the wiring layer 210. More particularly, one part of the conductive vias 252 electrically connect the wiring layer 230 to the wiring layer 232, and another part of the conductive vias 252 electrically connect the wiring layer 232 to the wiring layer 210.

As such, the chip 220 and the chip 222 are electrically connected to the wiring layer 210 through the conductive vias 250, the wiring layer 230, the wiring layer 232, and the conductive vias 252. That is, if the chip 220 and the chip 222 are memory chips, the user may access digital data of the chip 220 and the chip 222 through the contacts 212 of the wiring layer 210.

It should be noted that the chip package 200 provided by the present invention is not used to limit the number of layers of the wiring layers (e.g., the wiring layer 230 and the wiring layer 232) and the number of the chips (e.g., the chip 220 and the chip 222).

In other embodiments of the present invention, the chip package further comprises more than three wiring layers and more than three chips. Definitely, as mentioned in the above embodiments, the chips are also electrically connected to other wiring layers through the conductive vias and the connected wiring layers.

In the embodiment of the present invention, the chip package 200 further comprises a protective layer 260. The protective layer 260 is disposed on the surface of the wiring layer 210, where the surface is away from the dielectric layer 240. The protective layer 260 has a plurality of openings 262, wherein the openings 262 expose a part of the contacts 212.

Further, the chip package 200 comprises a protective layer 270, wherein the protective layer 270 is disposed above the chip 220, the chip 222, the wiring layer 230, and the wiring layer 232.

In the present embodiment, the protective layers 260 and 270 may be made of an insulating material. The insulating material may be an electric charge-preventing material or a damp-proof material.

Referring to FIG. 2, the chip package 200 further comprises a protrusion 280 and a chamfer 310 for the user to conveniently plug or remove the chip package 200, wherein the protrusion 280 is disposed on the protective layer 270.

In some embodiments of the present invention, to achieve a better electrical property of the chip package 200, a passive component 300 is disposed in the dielectric layer 240. Referring to FIG. 2, the passive component 300 is electrically connected to the wiring layer 210.

Definitely, in other embodiments of the present invention, the chip package may further comprises a plurality of passive components, wherein the passive components are electrically connected to the chip 220 or the chip 222.

In the present invention, the passive component 300 is an independent electronic component. Or the passive component 300 may be electrically connected to the wiring layer 230 (not shown).

In the present invention, the passive component 300 may be a capacitor, a resistor, or an inductor.

To control the chip 220 and the chip 222, in some embodiments of the present invention, the chip package 200 further comprises a control unit 290, wherein the control unit 290 is electrically connected to the chip 220 and the chip 222. More particularly, the control unit 290 is disposed in the dielectric layer 240, and is electrically connected to the wiring layer 230 through the conductive vias 250. In this manner, the control unit 290 may control the chip 220 and the chip 222 through the conductive vias 250, the wiring layer 230, the wiring layer 232, and the conductive vias 252.

In other embodiments of the present invention, the control unit 290 may be disposed in the dielectric layer 240 (not shown) and electrically connected to the wiring layer 210. In this manner, the control unit 290 may control the chip 220 and the chip 222 through the conductive vias 250, the conductive vias 252, the wiring layer 230, the wiring layer 232, and the wiring layer 210.

In the above embodiment, although the active surface 220a and the active surface 222a face in the same direction, such chip arrangement is not intended to limit the present invention. The active surfaces of the chips may face in the different directions in another embodiment of the present invention.

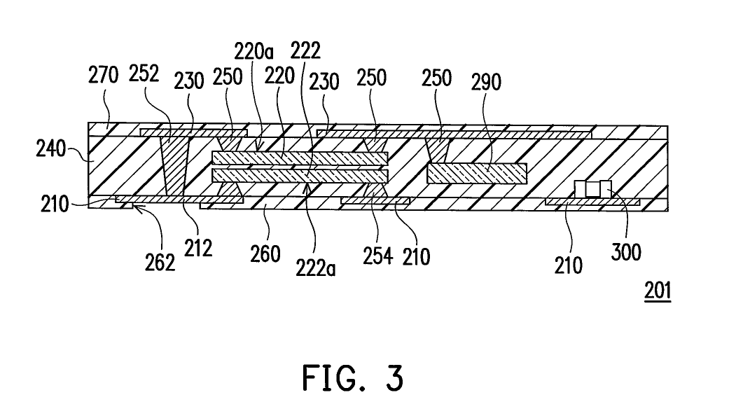

FIG. 3 is a schematic cross-sectional view of the chip package of another embodiment of the present invention.

Referring to FIG. 3, the chip package 201 mainly comprises a wiring layer 210, a chip 220, a chip 222, a wiring layer 230, a multi-layer dielectric layer 240, a plurality of conductive vias 250, a plurality of conductive vias 252, and a plurality of conductive vias 254.

The wiring layer 210 has a plurality of contacts 212, wherein the contacts 212 are near a side of the wiring layer 210.

The chip 220 has an active surface 220a, and the chip 222 has an active surface 222a. The chip 220 and the chip 222 are respectively stacked over the wiring layer 210, and the chip 222 is disposed between the chip 220 and the wiring layer 210. The active surface 220a and the active surface 222a face in the opposite directions respectively.

The wiring layer 230 is disposed over the chip 220. The multi-layer dielectric layer 240 have many dielectric layers that are respectively disposed between any adjacent two of the wiring layer 210, chip 220, chip 222, and wiring layer 230.

The conductive vias 250 are disposed in the dielectric layer 240 for electrically connecting the chip 220 to the wiring layer 230. The conductive vias 252 are disposed in the dielectric layer 240 for electrically connecting the wiring layer 230 to the wiring layer 210. The conductive vias 254 are also disposed in the dielectric layer 240 for electrically connecting the chip 222 to the wiring layer 210.

The chip 220 may be electrically connected to the wiring layer 210 through the conductive vias 250, the wiring layer 230, and the conductive vias 252. The chip 222 may be electrically connected to the wiring layer 210 through the conductive vias 254. That is, if the chip 220 and the chip 222 are memory chips, the user may access the digital data of the chip 220 and the chip 222 through the contacts 212 of the wiring layer 210.

In the embodiments with respect to FIG. 3, to achieve a better electrical property of the chip package 200, a passive component 300 is disposed in the dielectric layer 240. The using manner of the passive component 300 is described in the embodiment of FIG. 2.

Referring to FIG. 3, in the present invention, to control the chip 220 and the chip 222, the chip package 200 may further have a control unit 290, and the using manner of the control unit 290 is described in the embodiments of FIG. 2.

Further, the control unit 290 may also be disposed in the dielectric layer 240 (not shown in FIG. 3) and be electrically connected to the wiring layer 210. In this manner, the control unit 290 may control the chip 220 and the chip 222 through the conductive vias 250, 252, and 254 and the wiring layer 210 and 230.

It should be noted that the chip package 201 provided by the present invention is not intended to limit the number of layers of the wiring layer (e.g., the wiring layer 230), and the number of the chips (e.g., the chip 220 and the chip 222). It is known to those skilled in the art that combinations and changes may be made in other embodiments of the present invention such that the chip package may have more than two wiring layers and more than three chips and such that the active surface of at least one of some chips and the active surface of other chips face in the opposite directions respectively.

The chip package 201 may further comprises a protective layer 260. The protective layer 260 is disposed on the surface of the wiring layer 210, where the surface is away from the dielectric layer 240. The protective layer 260 has a plurality of openings 262, wherein the openings 262 expose a part of the contacts 212.

The chip package 201 may further comprises a protective layer 270, wherein the protective layer 270 is disposed on the wiring layer 230.

In the present invention, the protective layers 260 and 270 are made of the insulating material. The insulating material may be an electric charge-preventing material or a damp-proof material.

Besides, the chip package 201 may further comprises a protrusion and a chamfer (not shown in FIG. 3), for the user to conveniently plug or remove the chip package 201, wherein the protrusion is disposed on the protective layer 270.

In the above embodiments, i.e. in the chip package 200 and the chip package 201, the user may electrically connect the transmission apparatus (not shown) to the contacts 212 through the opening 262 of the protective layer 260 and access the digital data of the chip 220 and the chip 222 through the contacts 212.

The above embodiments are not intended to limit the present invention, and those skilled in the art may make appropriate modifications to the structure of the chip package, so as to change the electrical connecting manner of the chip package and the transmission apparatus of the present invention. Another possible arrangement of contacts of the wiring layer is described in the following.

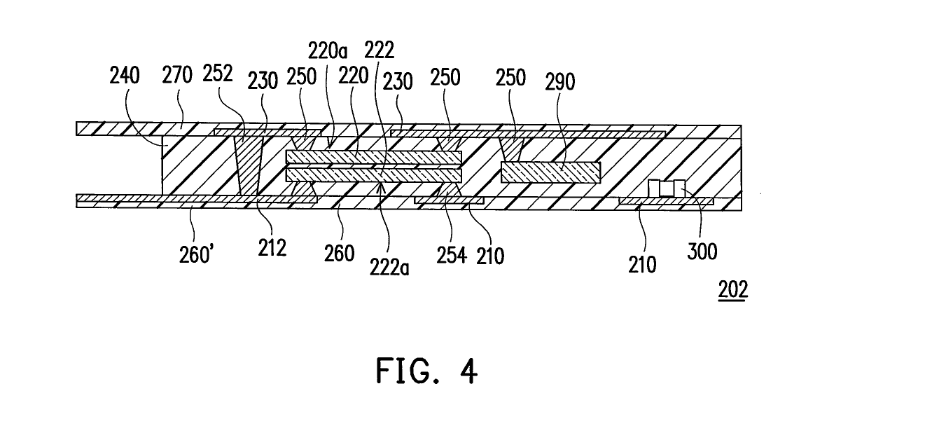

FIG. 4 is a schematic cross-sectional view of the chip package of still another embodiment of the present invention.

The embodiment of FIG. 4 is the transformation of the embodiment of FIG. 3. Therefore, the features described in FIG. 3 may also be used in the embodiment of FIG. 4 unless the difference is pointed out.

Referring to FIG. 4, the difference between the chip package 202 and the chip package 201 is that the arrangement of contacts 212 of the chip package 202 is different from the arrangement of contacts 212 of the chip package 201.

More particularly, referring to FIG. 4, the dielectric layer 240 of the chip package 202 does not cover the contacts 212, and the chip package 202 has a protective layer 260′ disposed on the surface of the wiring layer 210, where the surface is away from the dielectric layer 240. In this manner, the user may access the digital data of the chip 220 and the chip 222 through the contacts 212, wherein the contacts 212 are exposed by the dielectric layer 240.

In the present invention, the protective layer 260′ may be made of, for example, the material such as the protective layer 260 of FIG. 3.

To sum up, the present invention has at least the following advantages:

1. Compared with the conventional art in which the stacked chip package structure is fabricated through the wire bonding process by using the spacers, since the conductive via and the wiring layer (e.g. the wiring layer 232) adopted by the present invention have relatively thin thickness, the present invention can accomplish the electrical connecting of the chip and the wiring layer (e.g. the wiring layer 210) under the requirement of relatively thin thickness. Therefore, the chip package provided by the present invention has the relatively thin thickness, and a relatively short signal transmission path between the chip and the wiring layer (e.g. the wiring layer 210) can be achieved.

2. Since in the present invention, parts such as the conductive via, the wiring layer, and the dielectric layer, can be accomplished by electroplating, lithography/etching, spin coating, and other processes, the present invention can complete fabricating the chip package in a single plant and a single product line. Therefore, compared with the conventional art, the chip package provided by the present invention has the advantage of low cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip package, comprising:
a first wiring layer having a plurality of contacts in a side of the first wiring layer;
a plurality of chips stacked over the first wiring layer;
at least a second wiring layer stacked over the first wiring layer;
a plurality of dielectric layers disposed among the first wiring layer, the chips, and the second wiring layer respectively;
a plurality of first conductive vias inside at least one of the dielectric layers, for electrically connecting the chips to the second wiring layer; and
a plurality of second conductive vias inside at least one of the dielectric layers, for electrically connecting the second wiring layer to the first wiring layer.

2. The chip package as claimed in claim 1, further comprising a first protective layer disposed on a surface of the first wiring layer and having a plurality of openings for exposing a part of the contacts.

3. The chip package as claimed in claim 1, further comprising a second protective layer disposed over the second wiring layer.

4. The chip package as claimed in claim 3, further comprising a protrusion disposed on the second protective layer.

5. The chip package as claimed in claim 1, wherein one of the dielectric layers covers one of the contacts.

6. The chip package as claimed in claim 5, further comprising a third protective layer disposed on a surface of the first wiring layer.

7. The chip package as claimed in claim 1, further comprising a plurality of third conductive vias inside the dielectric layers for electrically connecting at least one of the chips to the first wiring layer.

8. The chip package as claimed in claim 1, further comprising a passive component being electrically connected to at least one of the wiring layers.

9. The chip package as claimed in claim 1, further comprising a control unit being electrically connected to at least one of the chips.

10. The chip package as claimed in claim 1, further comprising a chamfer on a side of one dielectric layer where at least one of the wiring layers is located.

11. A chip package, comprising:
a dielectric layer having a first side and a second side;
a first chip disposed in the dielectric layer;
a second chip disposed in the dielectric layer;
a first wiring layer disposed at the first side surface; and
a second wiring layer disposed at the second side surface;
wherein the first chip is electrically connected to the first wiring layer, the second chip is electrically connected to the second wiring layer, and the first wiring layer is electrically connected to the second wiring layer.

12. The chip package as claimed in claim 11, further comprising a third wiring layer disposed in the dielectric layer, wherein the third wiring layer is electrically connected to the first wiring layer and the second wiring layer.

13. The chip package as claimed in claim 12, wherein at least one of the first and second chips is electrically connected to at least one of the first and second wiring layers through the third wiring layer.

14. The chip package as claimed in claim 11, further comprising a third chip disposed in the dielectric layer, wherein the third chip is electrically connected to at least one of the wiring layers.

15. The chip package as claimed in claim 14, wherein the third chip is electrically to the second chip through at least one of the wiring layers.

16. The chip package as claimed in claim 11, further comprising a first passive component disposed in the dielectric layer and electrically connected to at least one of the wiring layers.

17. The chip package as claimed in claim 11, further comprising a first protective layer disposed on the first side surface.

18. The chip package as claimed in claim 17, further comprising a chamfer disposed on the first protective layer.

19. The chip package as claimed in claim 11, further comprising a second protective layer disposed on the second wiring layer.

20. The chip package as claimed in claim 19, further comprising a protrusion disposed on the second protective layer.
